(19) United States
(12) Patent Application Publication
(10) Pub. No.: US 2013/0285520 A1
(43) Pub. Date: Oct. 31, 2013

(54) ELECTRONIC DEVICE AND PANEL ASSEMBLY THEREOF

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventors: CHIN-SUNG YANG, New Taipei (TW); WEI LIU, Shenzhen (CN); XUE-DONG TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/688,742

(22) Filed: Nov. 29, 2012

(30) Foreign Application Priority Data
Apr. 25, 2012 (CN) 201210123393.6

(51) Int. Cl. H05K 5/03

(52) U.S. Cl. CPC H05K 5/03
USPC 312/223.1; 312/352

(57) ABSTRACT

A panel assembly includes a first panel having a body and a mating portion formed at an end of the body. The body includes a first surface and an opposite second surface, and the first surface includes several first hooking members and several protruding tabs. A second panel includes a first side and an opposite second side, the first side includes several resilient tabs and several second hooking members. Each resilient tab defines a receiving hole, and the second panel further has a top surface and a bottom surface that includes a protruding portion at the second side. The mating portion of the first panel is snugly received in the chamber, the first hooking members engage the second hooking members, and each of the tabs of the first panel is received in one of the receiving holes of the resilient tabs, thereby coupling the second panel to the first panel.

### BACKGROUND

1. Technical Field

The present disclosure relates to an electronic device and a panel assembly thereof.

2. Description of Related Art

Electronic device such as DVD players include a housing and a cover. One conventional cover includes two panels coupled to each other by screws. Although such conventional connection techniques can satisfy basic requirements, a panel assembly coupled together by a new connection technique is still needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of one embodiment of an electronic device.

FIG. 2 is an isometric, exploded view of the electronic device of FIG. 1.

FIG. 3 is an isometric partially exploded view similar to FIG. 2, but viewed from another viewpoint.

FIG. 4 is an assembled view of the elements of FIG. 3.

FIG. 5 is similar to FIG. 4, but viewed from another viewpoint.

FIG. 6 is an enlarged view of portion VI of FIG. 2.

FIG. 7 is a cross-sectional view taken along line VII-VII of FIG. 4.

### DETAILED DESCRIPTION

Embodiments of the present disclosure will be described with reference to the accompanying drawings.

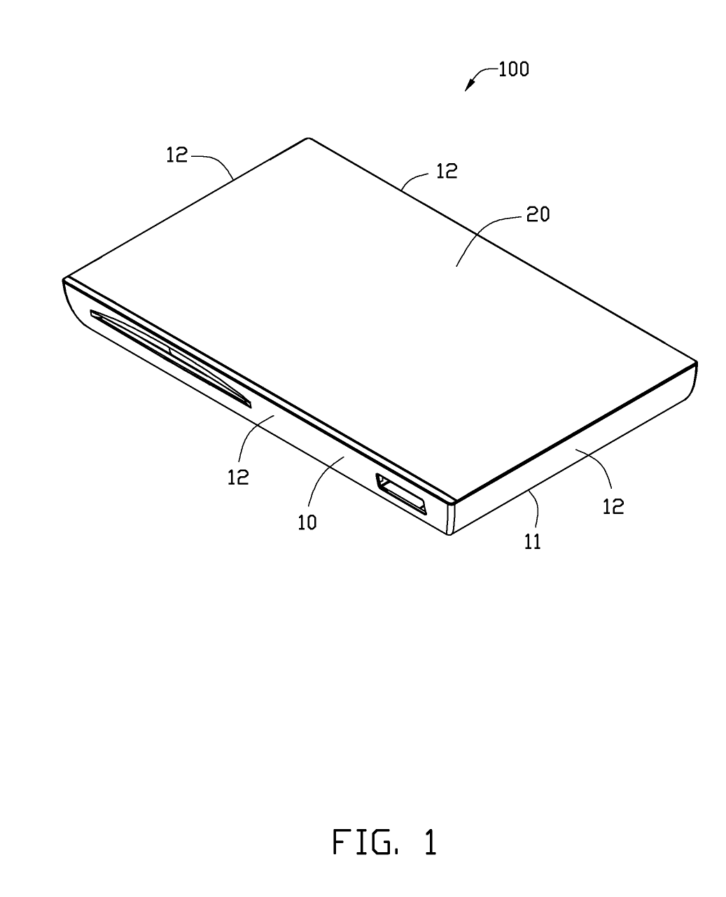

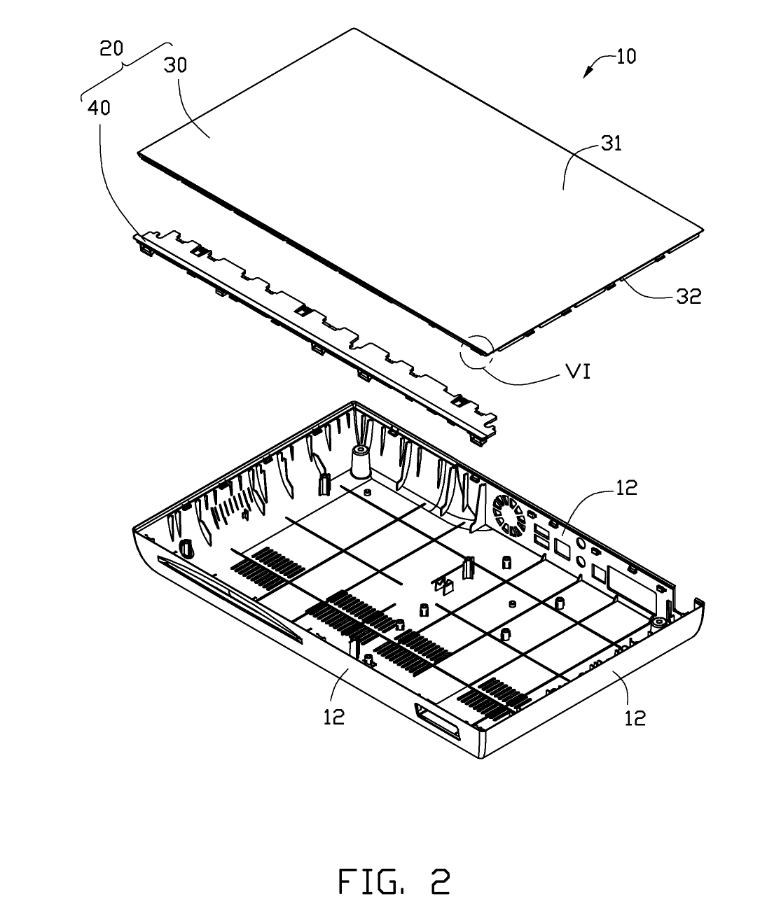

Referring to FIGS. 1 and 2, an electronic device 100 includes a housing 10 that includes a base 11, four side panels 12, and a cover 20. The cover 20 is a panel assembly including a first panel 30 and a second panel 40.

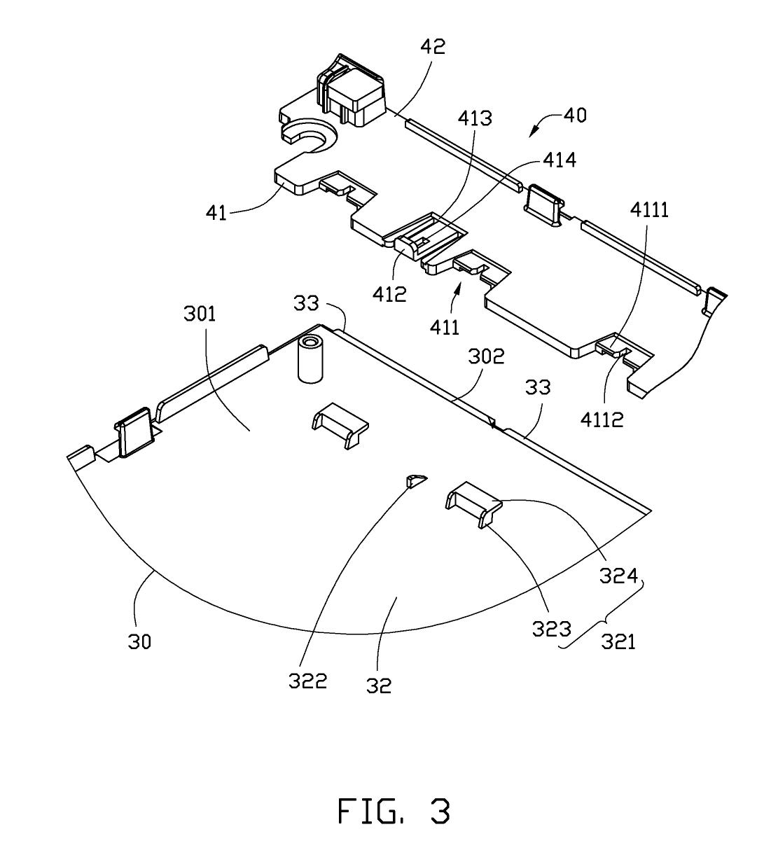

Referring to FIG. 3, the first panel 30 is a planar panel and includes a body 301 including an outer surface 31 and an inner surface 32. The inner surface 32 includes a number of first hooking members 321 and a number of tabs 322 adjacent to an end 302. The hooking members 321 are arranged along the end 302 and each include a vertical portion 323 protruding from the inner surface 32 and an angled portion 324 angled from an end of the vertical portion 323. Each tab 322 is arranged between two adjacent first hooking members 321. The first panel 30 further includes a mating portion 33 formed at the end 302.

The second panel 40 is elongated and includes a first side 41 and an opposite second side 42. The first side 41 defines a number of notches 411 and a number of resilient tabs 412. Each notch 411 includes a second hooking member 4111 accommodated therein. In the embodiment, each second hooking member 411 is a flat tab, and each resilient tab 412 is received in an opening 413. Each resilient tab 412 defines a receiving hole 414.

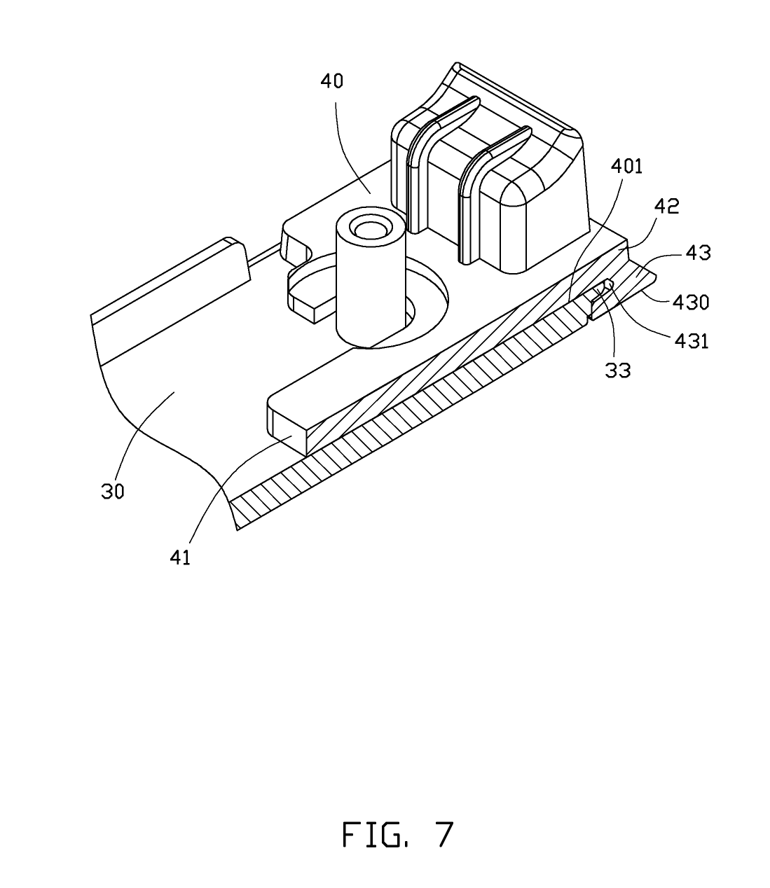

The second panel 40 further includes a surface 401 and a protruding portion 43 (FIG. 7) protruding from the surface 401 at the second side 42. The protruding portion 43 extends along a lengthwise direction and defines an open-ended chamber 431 extending along the full length of the protruding portion 43.

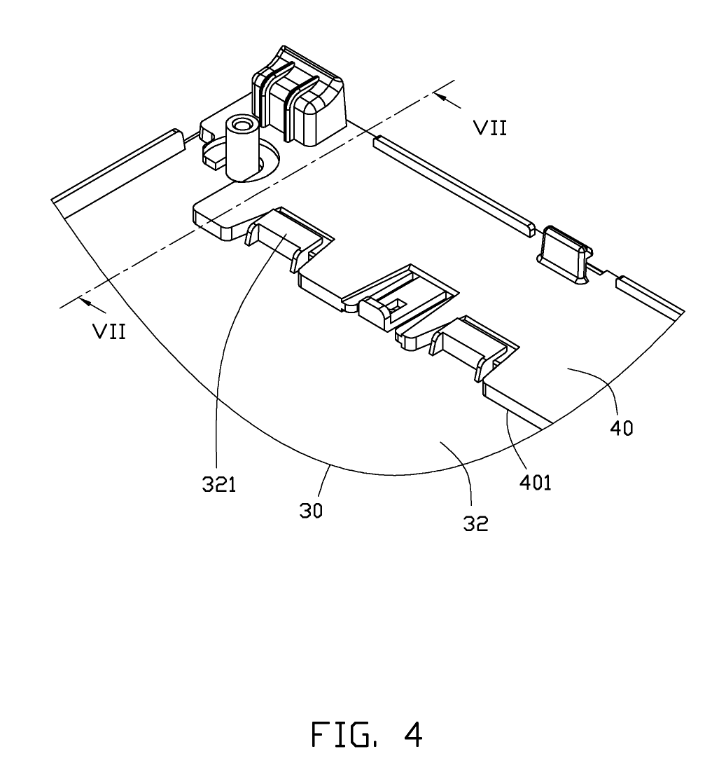

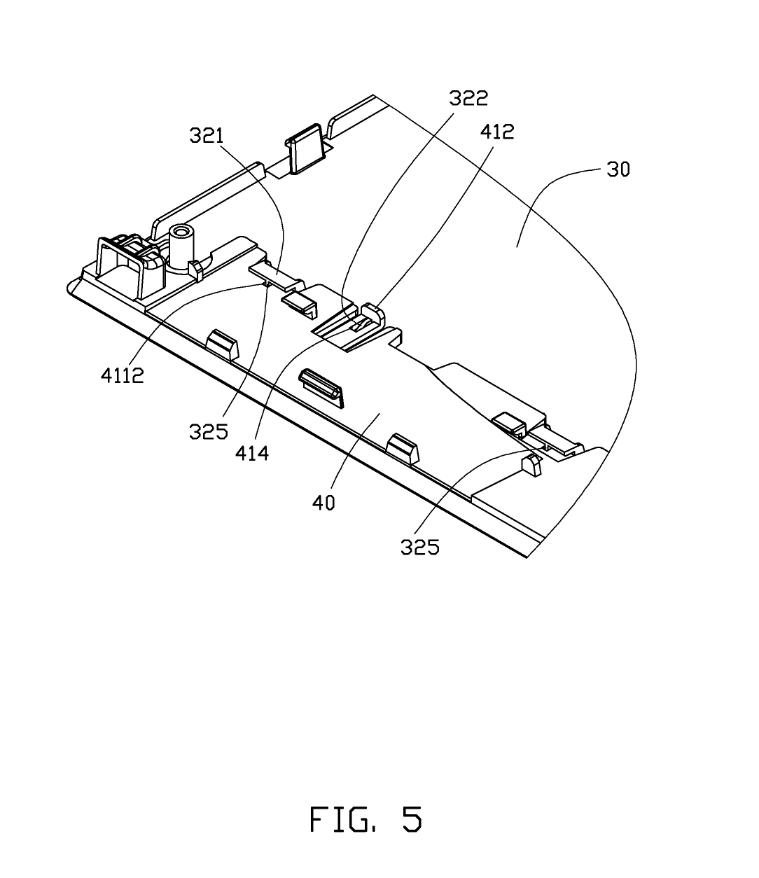

Referring to FIGS. 4 and 5, after assembly, the surface 401 of the second panel 40 is in full contact with the inner surface 32 of the first panel 30. Each first hooking member 321 is received in one notch 411 and engages the second hooking member 4111. That is, each angled portion 324 presses against the second hooking member 4111. Each tab 322 of the first panel 30 is received in one receiving hole 414 of the resilient tab 412, which prevents the second panel 40 from moving on the inner surface 32 of the first panel 30. As shown in FIG. 7, the mating portion 33 of the first panel 30 is a close fit in the chamber 431 of the second panel 40. With such a construction, the movement of the second panel 40 is completely restricted, and the second panel 40 is securely coupled to the first panel 30.

In one embodiment, each first hooking member 321 further includes a rib 325 protruding from the inner surface 32 of the first panel and terminating at the angled portion 324. Each second hooking member 4111 defines a slit 4112. Each rib 325 is a close fit in one slit 4112, which prevents the second panel 40 from moving along the end 302 of the first panel 30.

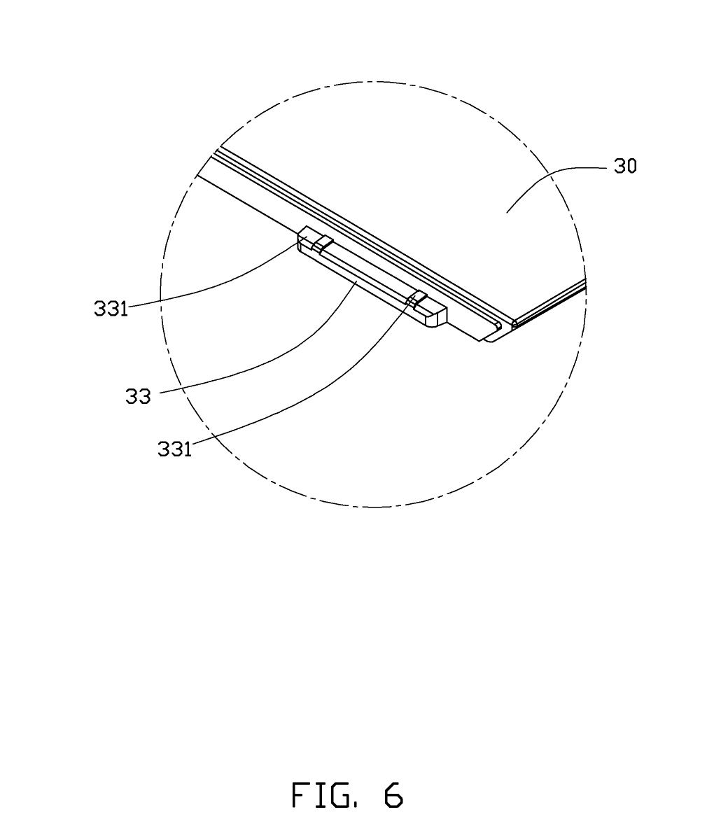

Referring to FIG. 6, the mating portion 33 is less thick than the body 301, which enables the outer surface 31 of the first panel 30 to be flush with the outer surface 430 of the protruding portion 43 of the second panel 40. The mating portion 33 further includes two small tabs 331 for amplifying the friction between the mating portion 33 and the inner surface of the chamber 431.

While various embodiments have been described and illustrated, the disclosure is not to be construed as being limited thereto. Various modifications can be made to the embodiments by those skilled in the art without departing from the true spirit and scope of the present disclosure as defined by the appended claims.

What is claimed is:

1. A panel assembly comprising:
a first panel comprising a body and a mating portion formed at an end of the body, the body comprising a first surface and an opposite second surface, the first surface comprising a plurality of first hooking members and a plurality of tabs protruding therefrom; and
a second panel comprising a first side and an opposite second side, the first side comprising a plurality of resilient tabs and a plurality of second hooking members, each of the resilient tabs defining a receiving hole, the second panel further comprising a top surface and a bottom surface that comprises a protruding portion protruding therefrom at the second side, the protruding portion defining a chamber;
wherein the mating portion of the first panel is snugly received in the chamber, the plurality of the first hooking members engage the plurality of the second hooking members, and each of the tabs of the first panel is received in one of the receiving holes of the resilient tabs, thereby coupling the second panel to the first panel.

2. The panel assembly according to claim 1, wherein the second panel defines a plurality of notches at the first side, and each of the second hooking members is received in one of the notches.

3. The panel assembly according to claim 2, wherein each of the second hooking members defines a slit, each of the first hooking members comprises a vertical portion protruding from the first surface, an angled portion, and a rib protruding from first surface and terminating at the angled portion, each rib is snugly received in one of the slits, thereby preventing the second panel from moving along the end of the first panel.

4. The panel assembly according to claim 1, wherein the mating portion has a thickness smaller than a thickness of the body, enabling the second surface of the first panel to be flush with an outer surface of the protruding portion.

5. An electronic device comprising:
a housing comprising a panel assembly, the panel assembly comprising:
a first panel comprising a body and a mating portion formed at an end of the body, the body comprising a first surface and an opposite second surface, the first surface comprising a plurality of first hooking members and a plurality of tabs protruding therefrom; and
a second panel comprising a first side and an opposite second side, the first side comprising a plurality of resilient tabs and a plurality of second hooking members, each of the resilient tabs defining a receiving hole, the second panel further comprising a top surface and a bottom surface that comprises a protruding portion protruding therefrom at the second side, the protruding portion defining a chamber;
wherein the mating portion of the first panel is snugly received in the chamber, the plurality of the first hooking members engage the plurality of the second hooking members, and each of the tabs of the first panel is received in one of the receiving holes of the resilient tabs, thereby coupling the second panel to the first panel.

6. The electronic device according to claim 5, wherein the second panel defines a plurality of notches at the first side, and each of the second hooking members is received in one of the notches.

7. The electronic device according to claim 6, wherein each of the second hooking members defines a slit, each of the first hooking members comprises a vertical portion protruding from the first surface, an angled portion, and a rib protruding from first surface and terminating at the vertical portion, each rib is snugly received in one of the slits, thereby preventing the second panel from moving along the end of the first panel.

8. The electronic device according to claim 5, wherein the mating portion has a thickness smaller than a thickness of the body, enabling the second surface of the first panel to be flush with an outer surface of the protruding portion.
